(19) United States
(12) Patent Application Publication
(10) Pub. No.: US 2015/0118416 A1
(43) Pub. Date: Apr. 30, 2015

(54) SUBSTRATE TREATING APPARATUS AND METHOD

(71) Applicant: Semes Co., Ltd., Cheonan-si (KR)

(72) Inventors: Yong Su JANG, Cheonan-si (KR); Sung Hwan HONG, Cheonan-si (KR)

(21) Appl. No.: 14/527,955

(22) Filed: Oct. 30, 2014

(30) Foreign Application Priority Data
Oct. 31, 2013 (KR) 10-2013-0131362
Dec. 23, 2013 (KR) 10-2013-0161677

(51) Int. Cl. C23C 16/455; C23C 16/511

(52) U.S. Cl. CPC C23C 16/45519; C23C 16/511
USPC 427/575; 118/723 AN

(57) ABSTRACT

Provided is a substrate treating apparatus. The substrate treating apparatus includes a processing chamber, a substrate supporting unit, an antenna plate, a dielectric plate, a gas supplying unit or the like. In the gas supplying unit, an excitation gas injection unit is provided at a position higher than that of a process injection unit so as to inject an excitation gas containing an inert gas from a position higher than that of a process gas, thereby preventing a damage of the dielectric plate, generating high-density plasma, and preventing degradation of process performance in a process which is performed under a process pressure of 50 mTorr or more or uses a hydrogen gas.

### CROSS-REFERENCE TO RELATED APPLICATIONS

This U.S. non-provisional patent application claims priority under 35 U.S.C. §119 of Korean Patent Application Nos. 10-2013-0131362, filed on Oct. 31, 2013, and 10-2013-0161677, filed on Dec. 23, 2013, the entire contents of which are hereby incorporated by reference.

### BACKGROUND OF THE INVENTION

The present invention disclosed herein relates to a substrate treating apparatus and method, and more particularly, to a substrate treating apparatus and method using plasma.

Plasma is generated by an extremely high temperature, a strong electric field, or radio frequency (RF) electromagnetic field, and has an ionized gas state composed of ions, electrons, radicals, etc. A semiconductor device manufacturing process performs a thin film deposition process using plasma. The thin film deposition process is performed by depositing ion particles contained in plasma onto a substrate to form a thin film.

In general, a plasma treating apparatus supplies each of a process gas and a plasma excitation gas into a chamber, and then excites the process gas to a plasma state through high-frequency electric power applied from an antenna plate. A process gas injection hole for supplying a process gas and an excitation gas injection hole for supplying a plasma excitation gas are provided in an inner side of the chamber. The process gas injection hole and the excitation gas injection hole are alternately arranged at the same height.

However, when different types of gases are injected at the same height, if a distance between a dielectric plate and a substrate supporting unit is less than a predetermined distance, low electric power is used for preventing a substrate from being damaged because the temperature of an electron becomes higher as the electron is closer to a dielectric plate, so that it is impossible to generate high-density plasma. On the contrary, if a distance between the dielectric plate and the substrate supporting unit is greater than the predetermined distance, the dielectric plate is damaged by using a high electric power to uniformly form a film on the substrate. In addition, when a process is performed under a predetermined pressure or more, or a process involving a hydrogen gas is performed, substrate treating performance is degraded.

### SUMMARY OF THE INVENTION

The present invention provides a substrate treating apparatus and method, capable of forming high-density plasma.

The present invention also provides a substrate treating apparatus and method, capable of preventing a dielectric plate from being damaged.

The present invention also provides a substrate treating apparatus and method, which prevent degradation of process performance in a process performed under a predetermined pressure or more, and a process involving a hydrogen gas.

The object of the present invention is not limited to the aforesaid, but other objects not described herein will be clearly understood by those skilled in the art from descriptions below.

Embodiments of the present invention provide substrate treating apparatuses including: a processing chamber having an inner space; a substrate supporting unit disposed in the processing chamber and supporting a substrate; an antenna plate disposed above the substrate supporting unit and having a plurality of slots therein; a dielectric plate provided under the antenna plate, and allowing microwave to be propagated into and pass through the inner space of the processing chamber; and a gas supplying unit provided at a height between the dielectric plate and the substrate supporting unit, and supplying a gas into the processing chamber, wherein the gas supplying unit includes a first injection unit disposed at a first height and supplying a first gas and a second injection unit positioned at a second height which is lower than the first height, and supplying a second gas which differs in type from the first gas.

In some embodiments, the first injection unit may inject an exited gas and the second injection unit injects a process gas.

In other embodiments of the present invention, substrate treating apparatuses include the gas supplying unit including a third injection unit, wherein the third injection unit injects a cleaning gas.

In some embodiments, the third injection unit may be provided under the second injection unit.

In still other embodiments of the present invention, substrate treating methods using the substrate treating apparatus provide that a pressure in the processing chamber is 50 mTorr or more while a process is performed.

In even other embodiments of the present invention, substrate treating methods using the substrate treating apparatus provide that the second injection unit injects a process gas containing a hydrogen gas.

In some embodiments, an amount of the hydrogen gas may be not less than 20% of a total gas amount in the processing chamber.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of a substrate treating apparatus according to an embodiment of the present invention;

FIG. 2 is a perspective view of a gas supplying unit in FIG. 1;

FIG. 3 is a plane view of an antenna plate in FIG. 1; and

FIG. 4 is a cross-sectional view of a substrate treating apparatus according to another embodiment of the present invention.

### DETAILED DESCRIPTION OF PREFERRED EMBODIMENTS

Hereinafter, preferred embodiments of the present invention will be described below in more detail with reference to the accompanying drawings. The embodiments of the present invention may, however, be embodied in different forms and should not be construed as limited to the embodiments set forth herein. These embodiments are provided so that this disclosure will be thorough and complete, and will fully convey the concept of the present invention to those skilled in the art. Therefore, shapes of the elements illustrated in the figures are exaggerated for clarity.

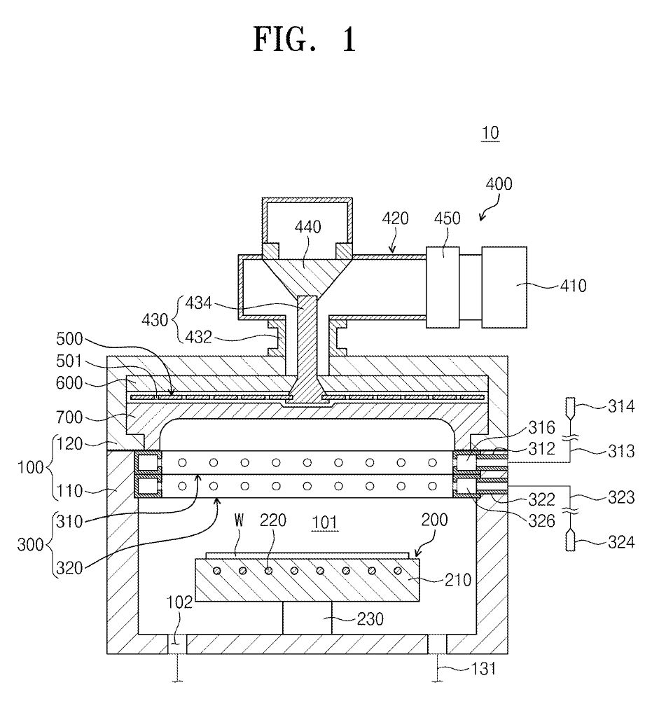

FIG. 1 is a cross-sectional view of a substrate treating apparatus 10 according to an embodiment of the present invention

Referring to FIG. 1, the substrate treating apparatus 10 performs a plasma process treatment on a substrate W. The substrate treating apparatus 10 includes a processing chamber 100, a substrate supporting unit 200, a gas supplying unit 300, a microwave applying unit 400, an antenna plate 500, a slow-wave plate 600, and a dielectric plate 700.

The processing chamber 100 has an inner space 101, and the inner space 101 is provided for performing a process of treating the substrate W. The processing chamber 100 includes a body 110 and a cover 120. The body 110 has an opened top surface and a space therein. The cover 120 is placed above the body 110 to seal the opened top surface of the body 110. An inner lower end of the cover 120 has a stepped portion such that an upper space has a radius greater than that of a lower space.

An opening (not shown) may be provided in a sidewall of the processing chamber 100. The opening provides a passage allowing the substrate W to be loaded into or unloaded from the processing chamber 100. The opening is opened and closed by a door (not shown).

An exhaust hole 102 is provided in a bottom surface of the processing chamber 100. The exhaust hole 102 is connected to an exhaust line 131. The processing chamber 100 may maintain an inner pressure lower than an atmospheric pressure by discharge through the exhaust line 131. By-products generated in a treating process and a residue gas staying in the processing chamber 100 may be discharged to the outside through the exhaust line 131.

The substrate supporting unit 200 is disposed in the processing chamber 100 and supports the substrate W. The substrate supporting unit 200 includes a supporting plate 210, a lift pin (not shown), a heater 220, and a supporting shaft 230.

The supporting plate 210 has a disc shape having a predetermined thickness and a radius greater than that of the substrate W. The substrate W is placed on the supporting plate 210. According to an embodiment, the supporting plate 210 is not provided with a structure for fixing the substrate W, and the substrate W is placed on the supporting plate 210 during the process. Alternatively, the supporting plate 210 may be provided as an electrostatic chuck for fixing the substrate W using an electrostatic force, or as a chuck for fixing the substrate W by a way of mechanical clamping.

The lift pin is provided in plurality and placed in each of pin holes (not shown) formed in the supporting plate 210. The lift pins move vertically along the pin holes, and loads or unloads the substrate W onto or from the supporting plate 210.

The heater 220 is provided in the supporting plate 210. The heater 220 may be provided with a coil having a spiral shape to be buried at equal intervals in the supporting plate 210. The heater 220 is connected to an external power supply (not shown), and generates heat by resisting against a current applied from the external power supply. The generated heat is transferred to the substrate W through the supporting plate 210 and heats the substrate W to a predetermined temperature.

The supporting shaft 230 is disposed under the supporting plate 210, and supports the supporting plate 210.

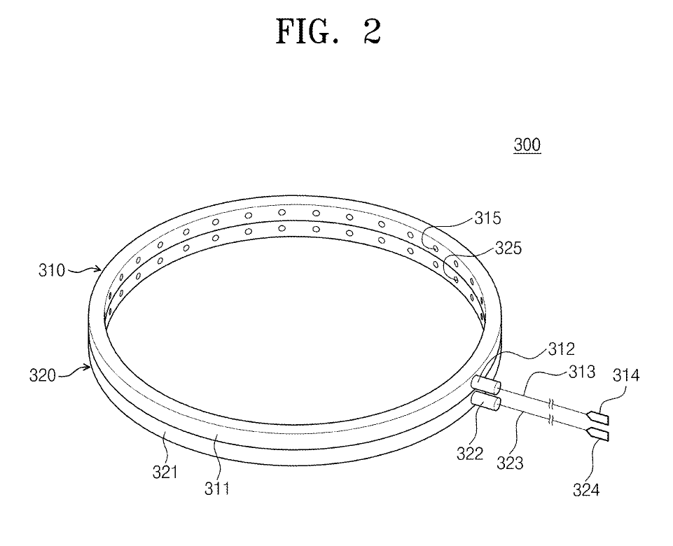

FIG. 2 is a perspective view of the gas supplying unit 300. Referring to FIGS. 1 and 2, the gas supplying unit 300 includes a first injection unit 310 and a second injection unit 320.

The first injection unit 310 supplies a first gas into the inner space 101. The first injection unit 310 includes a first ring 311, a first inlet port 312, a first gas supplying line 313, and a first gas supplying source 314. The first ring 311 has an annular ring shape. The first ring 311 is provided to surround an inner side of the processing chamber 100. The first ring 311 is disposed under the dielectric plate 700. A plurality of first gas injection holes 315 are formed in inner side of the first ring 311. The first gas injection holes 315 are arranged along a circumference of the first ring 311. Each of the first gas injection holes 315 is positioned at the same height. The first gas injection holes 315 are spaced at equal intervals. A first inlet port 312 is provided on an outer side of the first ring 311. A first connection flow path 316 connecting the first inlet port 312 and each of the first gas injection holes 315 is provided in the first ring 311. A first gas is introduced into the first connection flow path 316 through the first inlet port 312. The first connection flow path 316 distributes the first gas such that the first gas supplied to the first inlet port 312 is supplied to each of the first injection holes 315. For instance, the first gas may be an excitation gas.

Hereinafter, a wavelength of a microwave passing through the dielectric plate 700 is denoted by a reference symbol λ.

As an optimum plasma generation condition, a distance between the first gas injection hole 315 and the dielectric plate 700 may range from (⅛)λ to (⅜)λ. According to an embodiment, the distance between the first gas injection hole 315 and the dielectric plate 700 may be (¼)λ.

The second injection unit 320 supplies a second gas into the inner space 101. The second injection unit 320 includes a second ring 321, a second inlet port 322, a second gas supplying line 323, and a second gas supplying source 324. The second ring 321 has an annular ring shape. The second ring 321 is provided to surround an inner side of the processing chamber 100. The second ring 321 is disposed under the first ring 311. A plurality of second gas injection holes 325 are provided on an inner side of the second ring 321. The second gas injection holes 325 are arranged along a circumference of the second ring 321. Each of the second gas injection holes 325 is positioned at the same height. The second gas injection holes 325 are spaced at equal intervals. A second inlet port 322 is provided on an outer side of the second ring 321. A second connection flow path 326 connecting the second inlet port 322 and each of the second gas injection holes 325 is provided in the second ring 321. A second gas is introduced into the second connection flow path 326 through the second inlet port 322. The second connection flow path 326 distributes the second gas such that the second gas supplied to the second inlet port 322 is supplied to each of the second injection holes 325. For instance, the second gas may be a process gas.

As an optimum plasma generation condition, a distance between the first gas injection hole 315 and the second gas injection hole 325 may range from (⅛)λ to (⅜)λ. Also, a distance between the second gas injection hole 325 and the substrate W provided on the substrate supporting unit 200 may range from ( 2/8)λ to ( 4/8)λ. According to an embodiment, the distance between the first gas injection hole 315 and the second gas injection hole 325 may be (¼)λ. Also, a distance between the second gas injection hole 325 and the substrate W provided on the substrate supporting unit 200 may be ( 2/4)λ. In an embodiment, according to a wavelength of a microwave passing through the dielectric plate 700, a distance between the dielectric plate 700 and the substrate W provided on the substrate supporting unit 200 may be 120 mm.

As in the embodiment described above, when the first injection unit 310 and the second injection unit 320 are provided at different heights, the excitation gas containing an inert gas is injected above the process gas, thereby preventing a damage of the dielectric plate 700. Accordingly, the excitation gas may be injected closely to the dielectric plate 700 to generate high-density plasma. Also, even when a process is performed under a process pressure over a 50 mTorr or a process using a process gas or hydrogen gas (H₂) is performed, process performance is not degraded. According to an embodiment, when a process involving a hydrogen gas (H₂) is performed, the hydrogen gas (H₂) may be provided in an amount of not less than 20% of a total gas amount.

Referring to FIG. 1 again, the microwave applying unit 400 applies a microwave to the antenna plate 500. The microwave applying unit 400 includes a microwave generator 410, a first waveguide 420, a second waveguide 430, a phase shifter 440, and a matching network 450.

The microwave generator 410 generates a microwave.

The first waveguide 420 is connected to the microwave generator 410, and has an inner passage. The microwave generated from the microwave generator 410 is transferred to the phase shifter 440 through the first waveguide 420.

The second waveguide 430 includes an outer conductor 432 and an inner conductor 434.

The outer conductor 432 extends vertically downward from an end of the first waveguide 420 to form an inner passage. The outer conductor 432 has an upper end coupled to a lower end of the first waveguide 420, and a lower end coupled to an upper end of the cover 120.

The inner conductor 434 is disposed in the outer conductor 432. The inner conductor 434 is provided with a rod having a cylinder shape, of which a length direction is parallel to a vertical direction. An upper end of the inner conductor 434 is fixedly inserted into a lower end of the phase shifter 440. The inner conductor 434 extends downward and a lower end thereof is disposed in the processing chamber 100. The lower end of the inner conductor 434 is fixedly coupled to the center of the antenna plate 500. The inner conductor 434 is disposed perpendicular to a top surface of the antenna plate 500. The inner conductor 434 may be provided with a copper rod which is coated with a first plating film and a second plating film in sequence. According to an embodiment, the first plating film may be made of nickel (Ni) and the second plating film may be made of gold (Au) The microwave is propagated to the antenna plate 500 primarily through the first plating film.

The microwave which is phase-shifted by the phase shifter 440 is transferred to the antenna plate 500 through the second waveguide 430.

The phase shifter 440 is provided at a position where the first waveguide 420 and the second waveguide 430 are connected, and shifts a phase of the microwave. The phase shifter 440 may have a cone shape with a sharp bottom. The phase shifter 440 propagates the microwave transferred from the first waveguide 420 to the second waveguide 430 in a converted mode state. The phase shifter 440 may convert microwave from a TE mode to a TEM mode.

The matching network 450 is provided on the first waveguide 420. The matching network 450 matches the microwave propagated through the first waveguide 420 to a predetermined frequency.

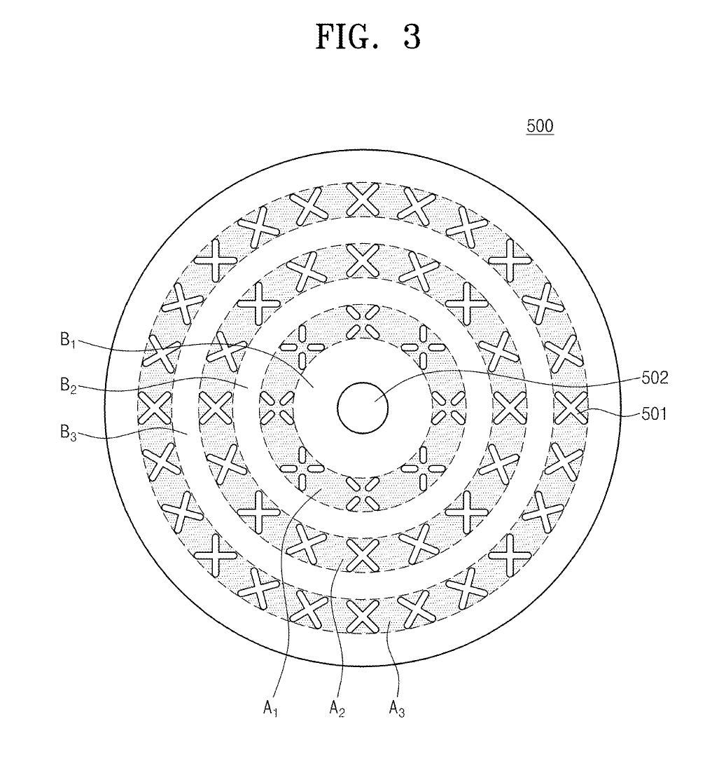

FIG. 3 is a view of a bottom surface of the antenna plate 500. Referring to FIGS. 1 and 3, the antenna plate 500 has a plate shape. For example, the antenna plate 500 may be provided to have a thin disc shape. The antenna plate 500 is disposed to face the supporting plate 210. A plurality of slots 501 are provided in the antenna plate 500. The slots 501 may have the shape of ‘X’. Alternatively, shapes and arrangement of slots may be diversely changed. The slots 501 are combined with each other in plurality and thus arranged in a shape of a plurality of rings. Hereinafter, areas of the antenna plate 500, in which the slots 501 are provided are called first areas A1, A2, and A3; and areas of the antenna plate 500, in which the slots 501 are not provided are called second areas B1, B2, and B3. Each of the first areas A1, A2, and A3 and the second areas B1, B2, and B3 has a ring shape. The first areas A1, A2, and A3 are provided in plurality and have different radii from each other. The first areas A1, A2, and A3 have the same center and are spaced from each other along a radial direction of the antenna plate 500. The second areas B1, B2, and B3 are provided in plurality and have different radii from each other. The second areas B1, B2, and B3 have the same center and are spaced from each other along a radial direction of the antenna plate 500. The first areas A1, A2, and A3 are placed among the second areas B1, B2, and B3. A hole 502 is provided at a central portion of the antenna plate 500. A lower end of the inner conductor 434 passes through the hole 502 to be coupled to the antenna plate 500. The microwave is transferred to the dielectric plate 700 through the slots 501.

Referring to FIG. 1 again, the slow-wave plate 600 is disposed above the antenna plate 500 and is provided with a disc having a predetermined thickness. The slow-wave plate 600 may have a radius corresponding to an inner side of the cover 120. The slow-wave plate 600 is provided with dielectric substances such as alumina and quartz. The microwave propagated vertically through the inner conductor 434 is propagated in a radial direction of the slow-wave plate 600. The microwave propagated to the slow-wave plate 600 has a compressed wavelength and is resonated.

The dielectric plate 700 is disposed under the antenna plate 500 and is provided with a disc having a predetermined thickness. The dielectric plate 700 is provided with dielectric substances such as alumina and quartz. The dielectric plate 700 has a bottom surface provided with a concave surface recessed therein. The bottom surface of the dielectric plate 700 is positioned at the same height with the lower end of the cover 120. A side portion of the dielectric plate 700 has a stepped portion such that an upper end of the dielectric plate 700 is greater in radius than a lower end. The upper end of the dielectric plate 700 is placed on a stepped lower end of the cover 120. The lower end of the dielectric plate 700 has a radius smaller than that of the lower end of the cover 120. The microwave is radiated into the processing chamber 100 through the dielectric plate 700. An excitation gas supplied into the processing chamber 100 by an electric field of the radiated microwave is excited to plasma.

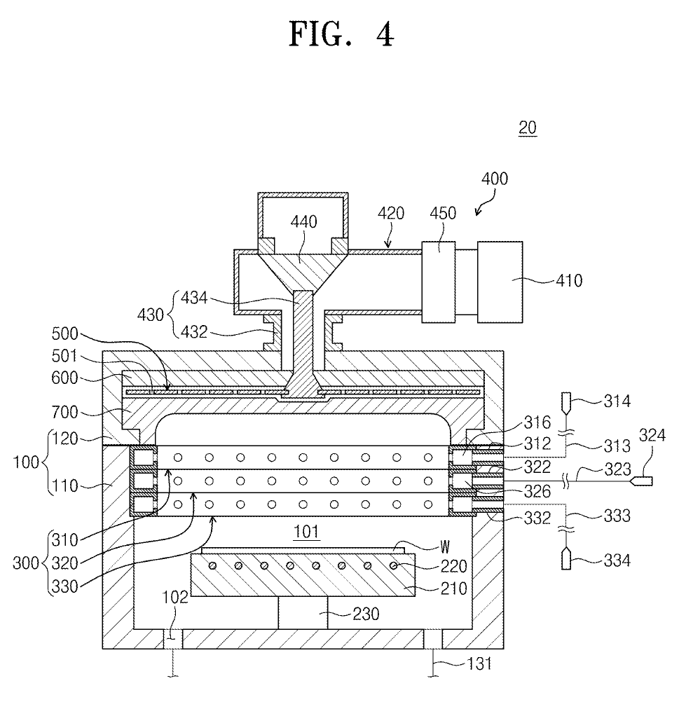

FIG. 4 is a cross-sectional view of a substrate treating apparatus 20 according to another embodiment of the present invention

Referring to FIG. 4, the gas supplying unit 300 further includes a third injection unit 330. The third injection unit 330 includes a third ring 331, a third inlet port 332, a third gas supplying line 333, and a third gas supplying source 334. The third injection unit 330 may be provided under the second injection unit 320. The third injection unit 330 injects a third gas into the processing chamber 100. The third gas may be a cleaning gas. A configuration, a structure, and the like of the third injection unit 330 are similar to those of the first and second injection units 310 and 320.

According to an embodiment of the present invention, the excitation gas is injected above the process gas, so as to prevent the dielectric plate from being damaged. Accordingly, the excitation gas may be injected within a predetermined distance to form high-density plasma.

According to an embodiment of the present invention, process performance may not be degraded even in a process which is performed under a predetermined pressure or more, or involves a hydrogen gas.

The above detailed description exemplifies embodiments of the present invention. Further, the above contents just illustrate and describe preferred embodiments of the present invention and an embodiment of the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. The above-mentioned embodiments are used to describe a best mode in implementing the inventive concept. An embodiment of the present invention can be implemented in a mode other than a mode known to the art by using another invention and various modifications required a detailed application field and usage of the present invention can be made. Therefore, the detailed description of embodiments of the present invention does not intend to limit the present invention to the disclosed embodiments. Further, the appended claims should be appreciated as a step including even another embodiment.

1. A substrate treating apparatus, comprising:
a processing chamber having an inner space;
a substrate supporting unit disposed in the processing chamber and supporting a substrate;
an antenna plate disposed above the substrate supporting unit and having a plurality of slots therein;
a dielectric plate provided under the antenna plate, and allowing microwave to be propagated into and pass through the inner space of the processing chamber; and
a gas supplying unit provided at a height between the dielectric plate and the substrate supporting unit, and supplying a gas into the processing chamber,
wherein the gas supplying unit comprises
a first injection unit disposed at a first height and supplying a first gas and
a second injection unit positioned at a second height which is lower than the first height, and supplying a second gas which differs in type from the first gas.

2. The substrate treating apparatus of claim 1, wherein the first injection unit injects an exited gas and the second injection unit injects a process gas.

3. The substrate treating apparatus of claim 2, wherein the first injection unit has a plurality of first gas injection holes therein, and the second injection unit has a plurality of second gas injection holes therein,
wherein each of the first and second injection units has a ring shape.

4. The substrate treating apparatus of claim 3, wherein when a wavelength of the microwave passing through the dielectric plate is λ, a distance between the dielectric plate and the first gas injection hole ranges from (⅛)λ to (⅜)λ.

5. The substrate treating apparatus of claim 3, wherein when a wavelength of the microwave passing through the dielectric plate is λ, a distance between the first gas injection hole and the second gas injection hole ranges from (⅛)λ to (⅜)λ.

6. The substrate treating apparatus of claim 3, wherein when a wavelength of the microwave passing through the dielectric plate is λ, a distance between the second gas injection hole and the substrate provided on the substrate supporting unit ranges from (⅜)λ to (⅝)λ.

7. The substrate treating apparatus of claim 4, wherein when a wavelength of the microwave passing through the dielectric plate is λ, a distance between the first gas injection hole and the second gas injection hole ranges from (⅛)λ to (⅜)λ, and a distance between the second gas injection hole 3 and the substrate provided on the substrate supporting unit ranges from (⅜)λ to (⅝)λ.

8. The substrate treating apparatus of claim 7, wherein a wavelength of the microwave passing through the dielectric plate is λ, a distance between the dielectric plate and the first gas injection hole and a distance between the first injection hole and the second injection hole are (¼)λ, and a distance between the second gas injection hole and the substrate supporting unit is ( 2/4)λ.

9. The substrate treating apparatus of claim 7, wherein a distance between the dielectric plate and the substrate supporting unit is 120 mm.

10. The substrate treating apparatus of any one of claim 1, wherein the gas supplying unit comprises a third injection unit,
wherein the third injection unit injects a cleaning gas.

11. The substrate treating apparatus of claim 10, wherein the third injection unit is provided under the second injection unit.

12. The substrate treating apparatus of claim 10, wherein the first injection unit has a plurality of first gas injection holes therein, the second injection unit has a plurality of second gas injection holes therein, and the third injection unit has a plurality of third gas injection holes therein,
wherein each of the first, second and third injection units has a ring shape.

13. The substrate treating apparatus of any one of claim 1, further comprising a slow-wave plate provided above the antenna plate and allowing a wavelength of the microwave to be shortened.

14. A substrate treating method using the substrate treating apparatus of claim 3, wherein a pressure in the processing chamber is 50 mTorr or more while a process is performed.

15. A substrate treating method using the substrate treating apparatus of claim 3, wherein the second injection unit injects a process gas containing a hydrogen gas.

16. The substrate treating method of claim 14, wherein an amount of the hydrogen gas is not less than 20% of a total gas amount in the processing chamber.
